(19) United States
(12) Patent Application Publication
(10) Pub. No.: US 2010/0013682 A1
(43) Pub. Date: Jan. 21, 2010

(54) Method for generic encoding, decoding and processing of protocol data units (PDUS)

(76) Inventor: Sahul Hameed Abdul Kader Jailani, San Jose, CA (US)

Correspondence Address: Sahul Hameed Abdul Kader Jailani, Apt 921, 4200 The Woods Drive, San Jose, CA, 95136, US

(21) Appl. No.: 12/176,366

(22) Filed: Jul. 19, 2008

(51) Int. Cl. H03M 7/00

(52) U.S. Cl. 341/79

(57) ABSTRACT

Devices using communication protocols encode, decode, process and display protocol data units (PDUS) using PDU specific procedures. This invention discloses a generic method to encode, decode, process and display the PDUS. A generic codec library provides generic encode, decode, process and display procedures. These generic procedures understand the PDU specific formats using the coding rules of the PDUS. The coding rules for PDUS are generated by a compiler tool from PDU definitions. Compiler parses PDU definitions specified in formal notation and generates the coding rules. These coding rules contain the information about PDU fields including names of the fields, types of the fields and size of the fields. This generic method supports mandatory fields, optional fields and variable length fields. This generic library in addition to encode, decode, display also process the PDUS to validate against the expected values for specified fields. The expected values are also specifiable in formal notation either as simple values or as run time expressions.

### CROSS-REFERENCE TO RELATED APPLICATIONS

Not Applicable

### STATEMENT REGARDING FEDERALLY SPONSORED RESEARCH

Not Applicable

### REFERENCE TO SEQUENCE LISTING

Not Applicable

### BACKGROUND OF THE INVENTION

1. Field of Invention

This invention relates to processing of network protocol data units exchanged by network devices.

2. Prior Art

Communication protocols are defined as set of Protocol Data Units (PDUS) exchanged and timely actions associated with those PDUS.

Software implementation of protocol involves the development of software to encoding and decoding of PDUS. Similarly implementation of testing tools to test these protocols also involves the development of software to encoding and decoding of PDUS.

Software implementations define PDUS as data structures. Application software either protocol state machine or test applications fill these data structures and use encoding function to prepare a PDU buffer for transfer over network. Similarly once receiving a PDU, decode function is invoked to decode the received PDU to populate the corresponding PDU data structure. The application software uses this populated structure to interpret the received information.

This method has the following disadvantages.
D1. Development of encoding and decoding software procedures becomes more complex for larger PDUS and with different types of information elements.
D2. Complex encoding and decoding software functions needs more testing time since they are error prone. Maintenance of these functions is a difficult task.
D3. Applications need to use PDU specific encoding or decoding functions for every PDU. This loads applications with more PDU specific processing.

Many improvements have been developed over the years on this PDU encoding and decoding methods. Formal notations to represent PDUS are developed. These formal notations opened up a way to automate the encoding decoding software development. Compilers are available to parse these formal notations and generate the software functions to encode and decode PDUS. These methods eliminated many of the disadvantages including D1 and D2 listed above. But still these methods do not solve the disadvantage D3.

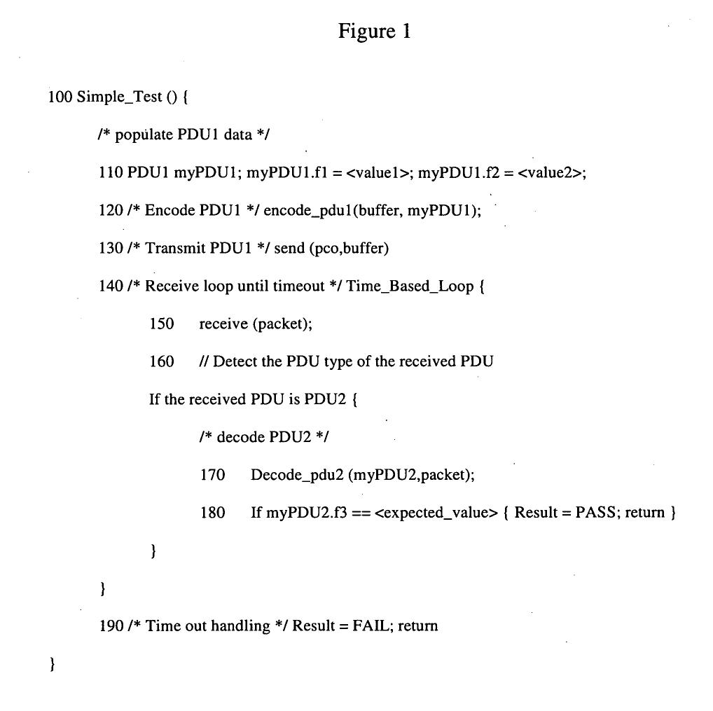

Applications need to use PDU specific encoding and decoding functions. A simple example of an application is shown in drawing FIG. 1. This drawing shows a test application function 100 Simple_Test( ). This Simple_Test function transmits a PDU1 with field f1 as <value1> and field f2 as <value2>. Then it expects a PDU2 with field 3 as <expected_value> within a predetermined time. If the PDU2 received on time with field 3 as <expected value> the result of this test application is considered pass. If expected PDU2 is not received within predetermined time, the result of this test application considered fail.

The step 110 has the pseudo code to populate the PDU1 data structure. It fills field f1, field f2 and also if any other mandatory fields required for PDU1. It uses PDU1 data structure defined by user or generated by a complier from formal representation of PDU1.

The step 120 invokes PDU specific encode function to encode PDU1. This encode function could be custom developed or generated by a compiler.

The step 130 invokes send function provided by Point of Control and Observation (PCO) software to transmit the PDU1.

The step 140 starts a time based loop to repeat the steps 150, 160 and 170 until timeout happens.

The step 150 invokes receive function provided by PCO to receive the PDUs.

The step 160 checks the type of the received PDU. It detects the received PDU type.

The step 170 decodes the received PDU if the received PDU is of type PDU2. This uses PDU specific decode function either customer developed or generated by a compiler.

The step 180 checks the value for field f3 in the received PDU2. If the expected value is received it declares the result of this test as pass and return.

The step 190 handles the time out case of not receiving expected PDU2 within time. It declares the test result as fail and return.

This Simple_Test( ) function also needs to take care of allocating memories and logging of PDUS sent and received.

On the above steps 110, 120, 160, 170 and 180 are PDU specific. This example clearly shows that applications still need lots of PDU specific processing steps.

### SUMMARY OF THE INVENTION

This invention discloses a generic method to encode, decode and process the PDUS. The generic codec (GCODEC) disclosed by this invention provides generic encode, decode, process and display procedures. These generic procedures understand the PDU specific formats using the coding rules of the PDUS. The coding rules for PDUS are generated by a compiler tool PANC from PDU definitions. PANC parses PDU definitions specified in formal notation (PAN) and generates the coding rules. PDU definitions from protocol standards need to be represented in PAN notation to use the generic codec procedures. A single generic encode procedure can be used to encode all the PDUS that are specified in PAN notation. This encode procedure reads the values from PDU structures and pack them as PDU buffer. The values in PDU structures can be populated in run time or also specified in PAN specifications. This approach of using single encode procedure for all PDUS is different from the prior arts that use PDU specific encode procedures to encode different PDUS.

Similarly a single generic decode procedure, process procedure and display procedure can be used by applications to decode, process and display all the PDUS specified in PAN notation.

The generic process procedure decodes the PDU and validate against the given expected values. The expected values also specified in PAN specifications. The PANC compiler parses the values specified in PAN specifications and generates PDU data. The generic process procedure uses this PDU data to validate the given PDU.

The generic display procedure decodes the PDU and generates tree structured ascii text of the decoded values. This display procedure is useful to display the PDUS to user.

This invention also discloses a method for enhanced send and receive functionalities by combing generic codec and transport procedures. The enhanced send method takes care of encoding the given PDU and transferring over the interface. The enhanced receive method takes care of receiving the PDUS and also validating PDUS for expected values using generic process procedure. This method of combing codec and transport procedures relieves applications from multiple PDU specific programming steps.

### BRIEF DESCRIPTION OF THE SEVERAL VIEWS OF THE DRAWING

The objects and features of the invention will be more understood with reference to the following description and the attached drawings, wherein:

Drawing FIG. 1 shows a simple application processing PDUS.

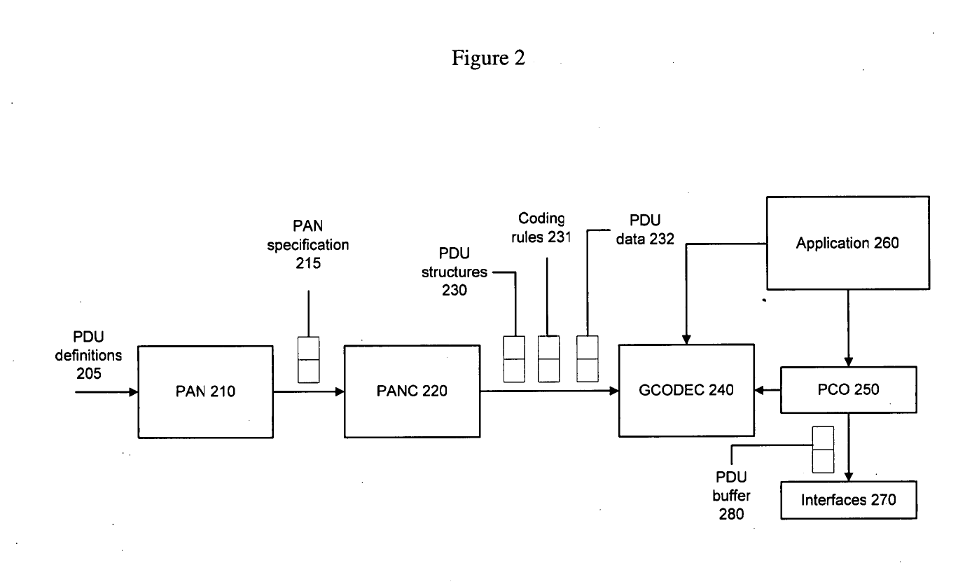

Drawing FIG. 2 shows the components of this invention PAN, PANC, GCODEC and PCO.

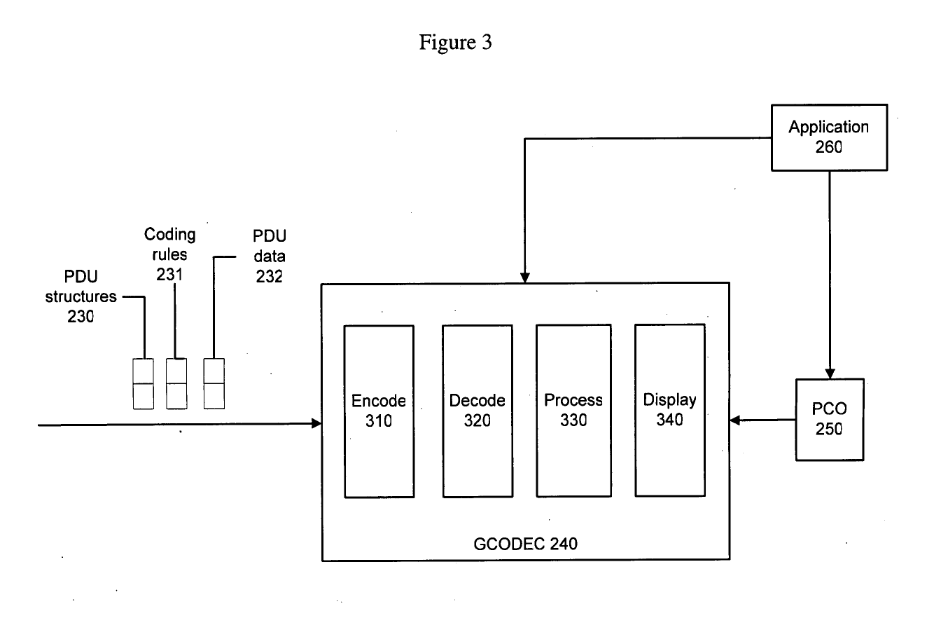

Drawing FIG. 3 shows the components of codec library GCODEC.

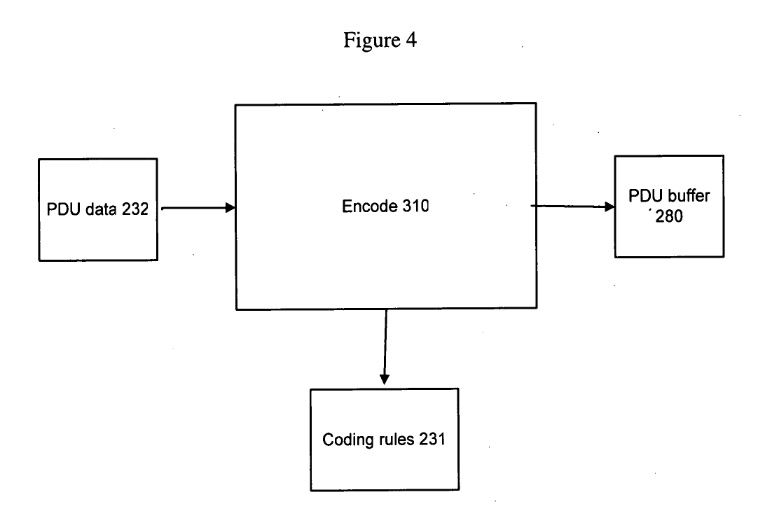

Drawing FIG. 4 shows the encoding procedure converting PDU structures into PDU buffer.

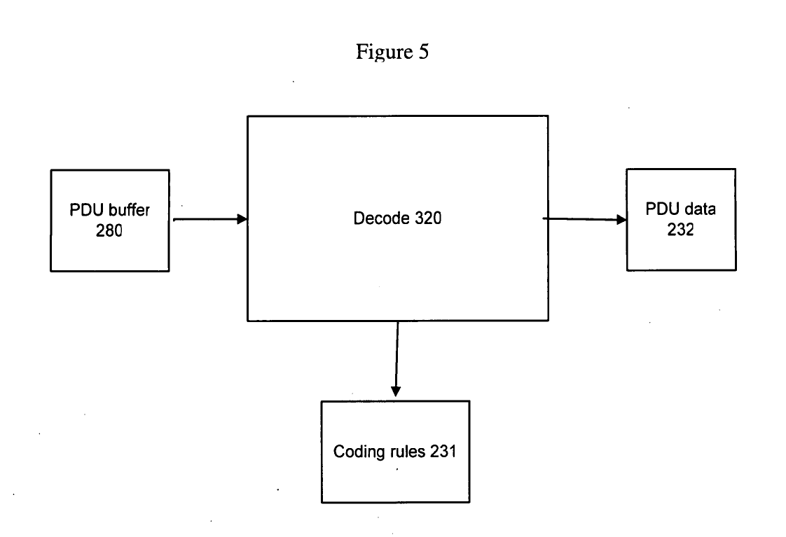

Drawing FIG. 5 shows the decoding of PDU buffer and populating PDU structures with the decoded information.

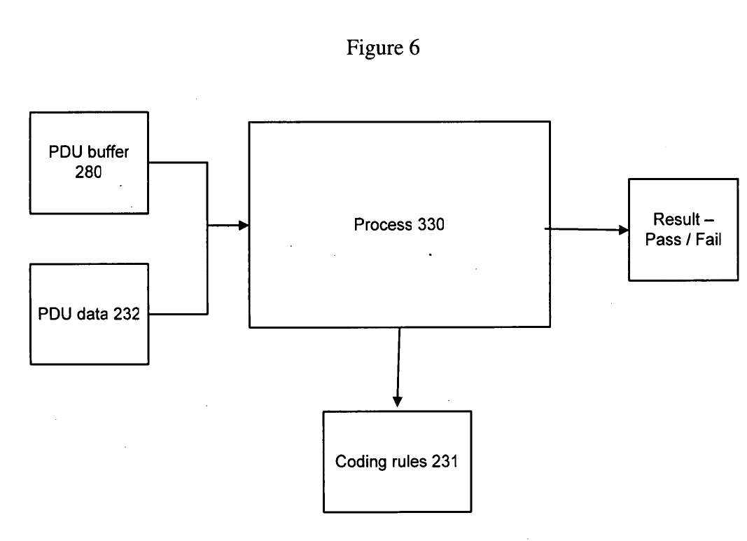

Drawing FIG. 6 shows process procedure decoding PDU buffer and validating with PDU data values.

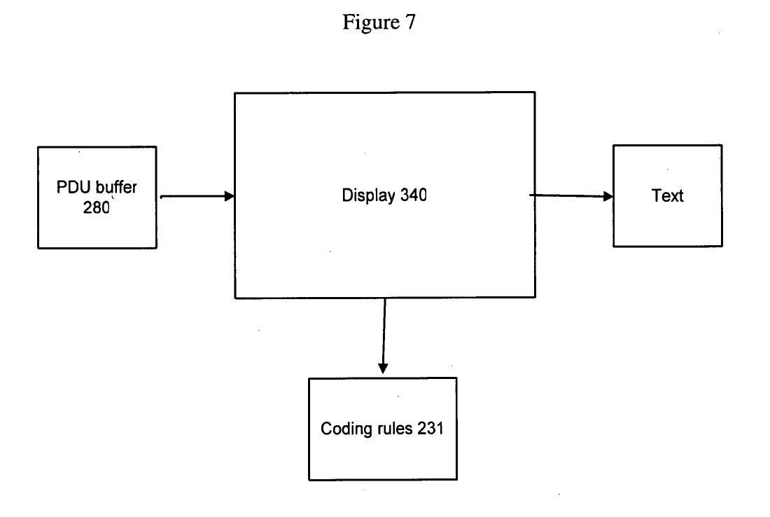

Drawing FIG. 7 shows display procedure decoding PDU buffer and displaying as text.

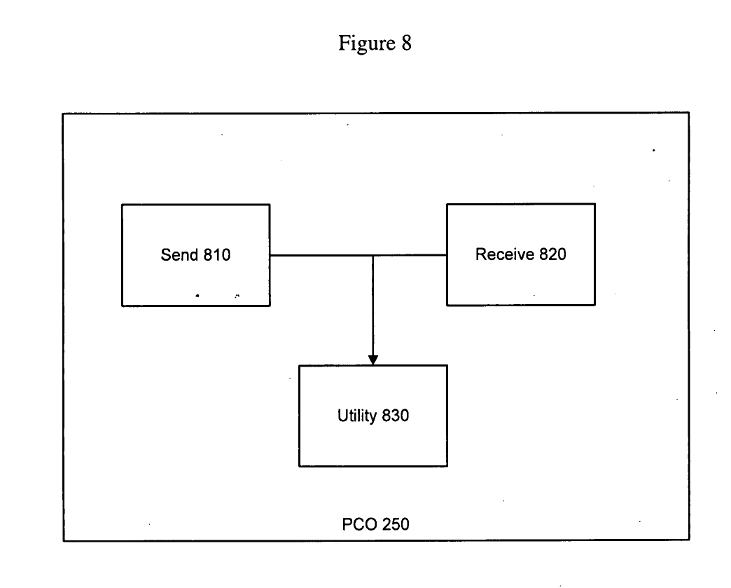

Drawing FIG. 8 shows the components of PCO.

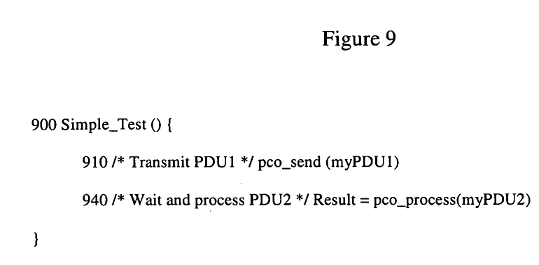

Drawing FIG. 9 shows the same application shown in drawing FIG. 1 using the method disclosed in this invention.

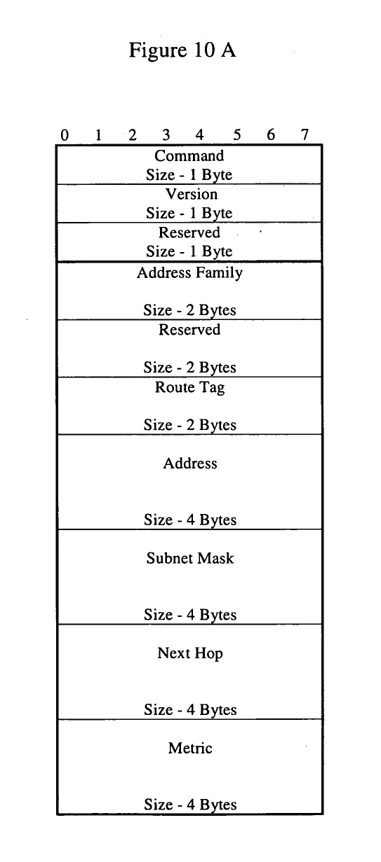

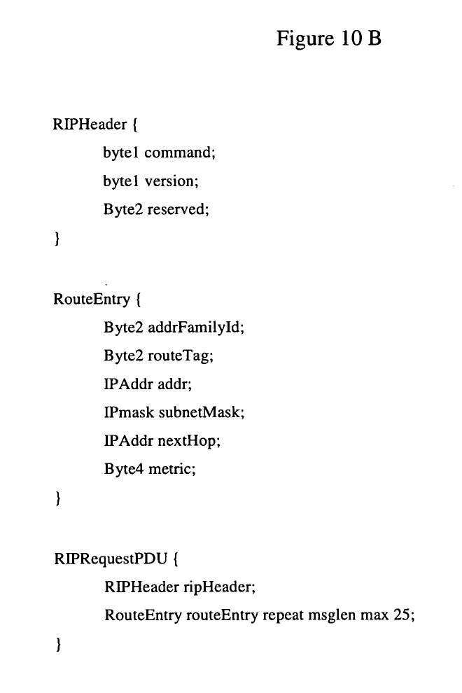

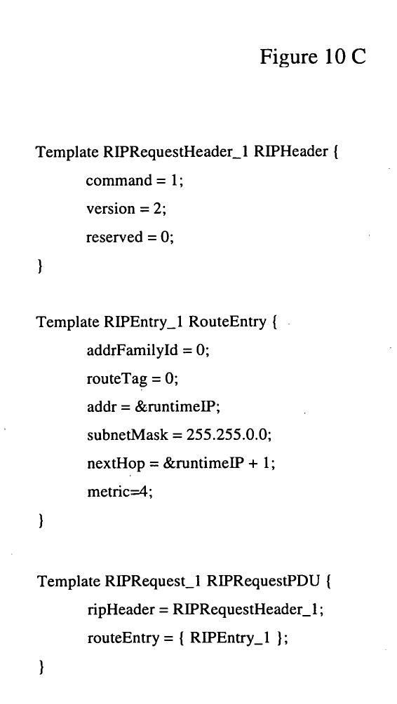

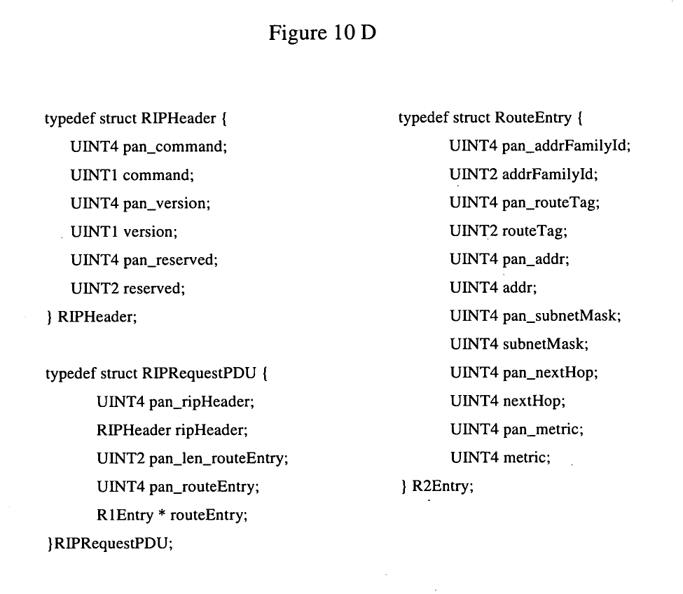

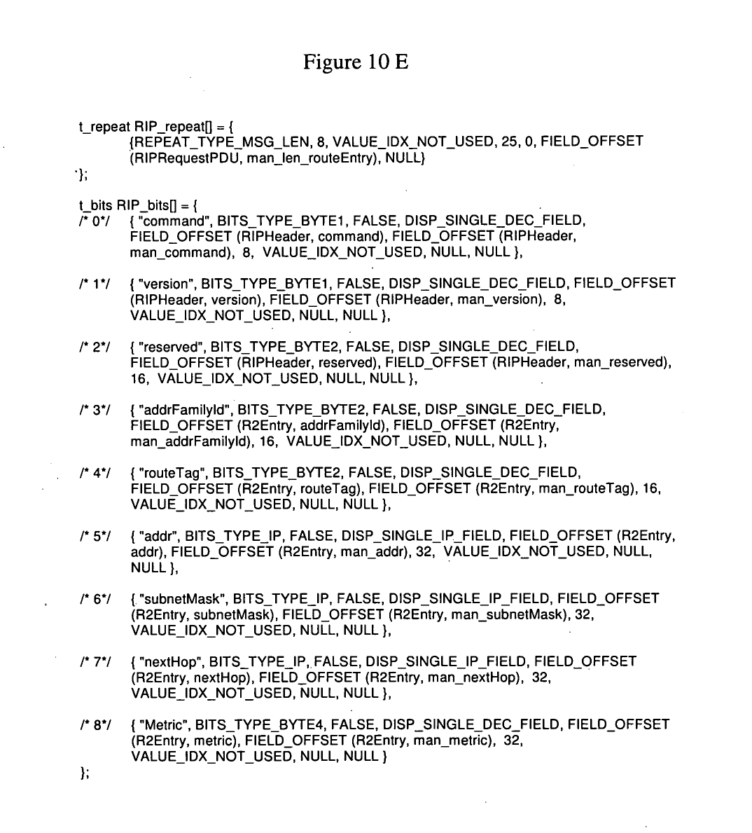

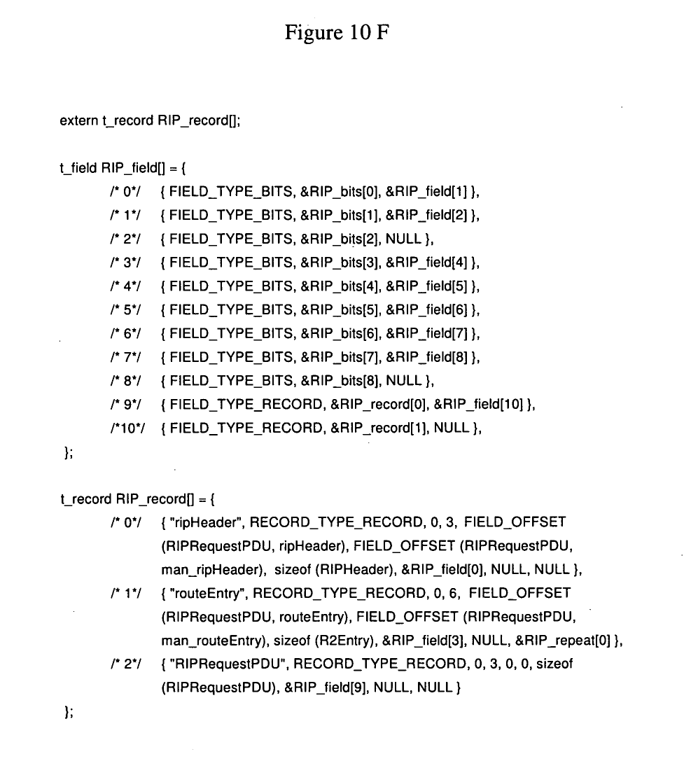

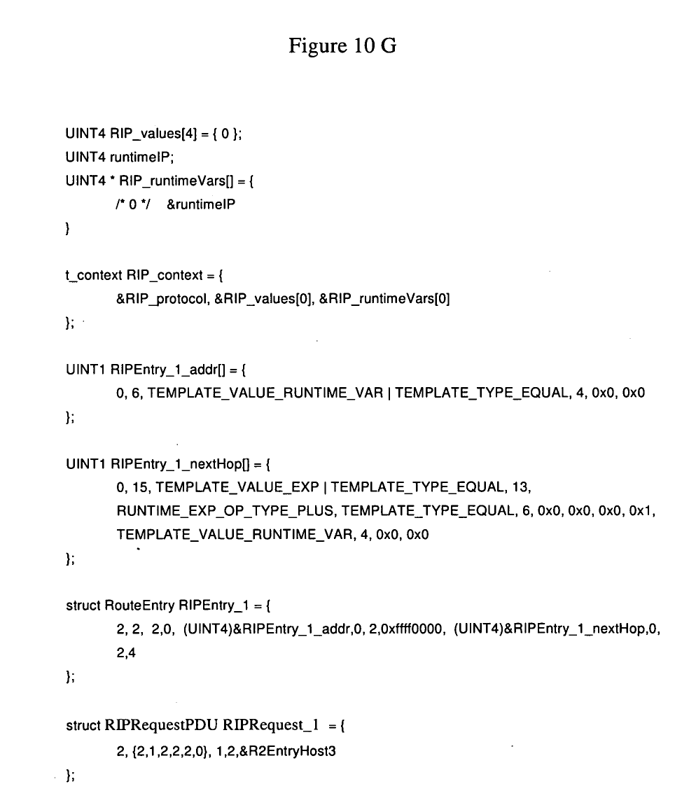

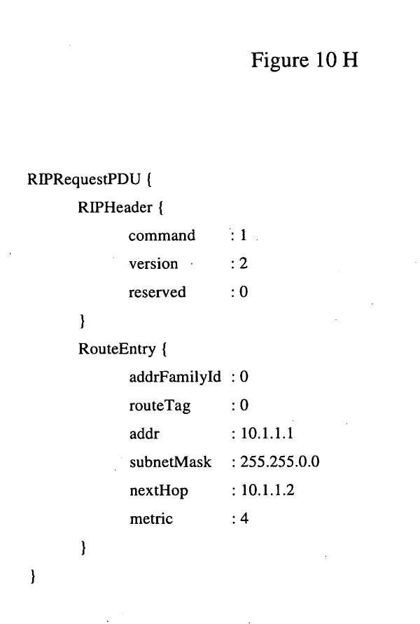

Drawing FIG. 10 A shows a PDU definition.

Drawing FIG. 10 B shows PAN specification for PDU shown in drawing FIG. 10 A.

Drawing FIG. 10 C shows PAN specification with values for PDU shown in drawing FIG. 10 A.

Drawing FIG. 10 D shows PDU structure generated by PANC for PAN specification shown in drawing FIG. 10 B.

Drawing FIG. 10 E shows part of coding rules generated by PANC for PAN specification shown in drawing FIG. 10 B. The remaining part of coding rules generated for this specification is shown in drawing FIG. 10 F.

Drawing FIG. 10 F shows part of coding rules generated by PANC for PAN specification shown in drawing FIG. 10 B.

Drawing FIG. 10 G shows PDU data generated from PAN specified values shown in drawing FIG. 10 C.

Drawing FIG. 10 H shows display text of PDU specified in drawing FIG. 10 B.

### DETAILED DESCRIPTION OF THE INVENTION

This invention discloses a generic method for encoding, decoding, processing and display of PDUS. This invention uses the following components to provide this solution PDU Abstraction Notation (PAN), PAN Compiler (PANC), Generic codec library (GCODEC) and PCO library (PCO). The drawing FIG. 2 shows these components PAN (210), PANC (220), GCODEC (240) and PCO (250).

PAN 210 is formal notation to represent the PDUS. The PDU definitions 205 available in protocol standards can be represented in PAN 210 notation as PAN specification 215. PAN 210 supports variety of data types to facilitate the representation of PDUS from many commonly used protocols. PAN 210 also provides facilities to provide the values for PDU fields.

PANC 220 is a compiler to parse PAN specifications 215 and generate information required for GCODEC 240. PANC 220 generates three types of information as PDU structures 230, coding rules 231, and PDU data 232. PDU structures 230 are representation of PDUS in programming language data structures. Coding rules 231 contain the information about fields in the PDU. This information helps GCODEC to understand the every field in the PDU and PDU structure 230. PDU data 232 contains the values to be coded in the PDUS.

GCODEC 240 consists of four different components encode 310, decode 320, process 330 and display 340 as shown in drawing FIG. 3.

Encode 310 converts the PDU data 232 to a transferable PDU buffer 280. Encode 310 uses coding rules 231 to understand PDU data and form the PDU buffer. The drawing FIG. 4 shows the encode 310.

Decode 320 coverts the PDU buffer 280 to PDU data 232. Decode 320 uses coding rules 231 to understand the PDU buffer and PDU data. The drawing FIG. 5 shows the decode 320.

Process 330 decodes the PDU buffer 280 and validate against the given PDU data 232. Process 330 provides the validated result as pass or fail. Process 330 uses coding rules to decode the PDU buffer and understand the PDU data. The drawing FIG. 6 shows the process 330.

Display 340 decodes the PDU buffer and generates tree formatted text of decoded PDU values. Display 340 uses coding rules to decode the PDU buffer. The drawing FIG. 7 shows the display 340.

PCO 250 takes care of sending and receiving PDU buffers over interfaces 270. The interfaces 270 can be of any physical or logical interface used for communication. PCO 250 contains three components send 810, receive 820 and utility 830 as shown in drawing FIG. 8.

The send 810 takes PDU data 232, uses encode 310 to convert PDU data as PDU buffer 280 and transfers it over interfaces 270.

The receive 820 receives the PDU buffer 280 from interfaces 270 and decode the buffer using decode 320. The receive 820 also uses process 330 to validate the received PDUS against provided PDU data.

The utility 830 provides the facilities for logging the PDUS sent and received through PCO 250. This utility 830 also provides the required timer support for receive 820.

The application 260 is any application software processing PDUS. It could be protocol implementation on devices like switches, routers, and any other communication devices. Also it could be tools application like traffic generators, protocol analyzers, and test suites. This invention attempts to make the development of the application 260 as simpler as possible.

The sample application Simple_Test( ) shown in drawing FIG. 1 is shown in drawing FIG. 9 using the new method disclosed in this invention. The Simple_Test( ) 900 shown in drawing FIG. 9 provides the same functionalities of Simple_Test( ) 100 shown in drawing FIG. 1.

The step 110 in drawing FIG. 1 is part of the PDU specifications in this new method. User can provide all the PDU values in PDU specification itself.

The steps 120 and 130 of drawing FIG. 1 are taken care by single step 910 in drawing FIG. 9.

The steps 140, 150, 160, 170, 180 and 190 are taken care by single step 920 in drawing FIG. 9. This is possible because PCO receive 820 takes care of receiving the PDU buffer and validating it using process 330. The values to be validated are specifiable in PDU specifications itself.

The step 910 and 920 also internally takes care of memory allocations and logging of sent and received PDUS.

This clearly shows the advantages on building applications using generic procedures disclosed in this invention.

The below texts provides the detailed description of the above discussed components.

PAN 210 provides data types to represent the PDUS in formal notation. PAN 210 provides the following data types to represent simple fields.

Byte1—To represent one byte fields

Byte2—To represent two bytes fields

Byte4—To represent 4 byte fields

Bits—To represent fields of few bits size

Hex—To represent longer fields in terms of bytes

Char—To represent character strings

IPAddr—To represent IP address in dotted notation like 10.10.10.10

IPMask—To represent IP subnet mask in dotted notation like 255.255.255.0

MACAddr—To represent MAC address like aa:bb:cc:dd:ee:ff

PAN 210 provides data types record and set to represent group fields. Record contains one or more fields as orderly list. Record can contain members of all the above basic types and group type members also of record or set. Set contains one more fields but the member fields can come in any order. This is useful to represent PDUS have optional fields expected in any order.

PAN 210 supports optionally present fields. Optional fields may present on the PDUS based on certain values of the same or other fields. PAN 210 provides a keyword “cond” to represent optional fields. This keyword “cond” usually comes with an expression to detect the presence of the specified optional fields at run time. The expression contains the names of the field(s) to check and the expected values to detect the presence of the associated optional field. The expression can contain relational and logical operators also.

PAN 210 also supports variable length fields. PAN 210 provides a keyword “repeat” to represent the variable length fields.

There are verities of variable length fields used in protocol messages. In general variable length fields have N number of bytes where N is derived from another simple prior field.

The prior field is called length field. PAN 210 provides a keyword “len” to represent the associated length fields.

The length field can have length in bits, bytes, or in any multiples. PAN 210 provides a keyword “mul” to represent the multiples.

In some case the length field might hold the number of times that variable length field repeats instead of length values in bits/bytes. PAN 210 provides keyword “num” to represent these fields.

Some fields repeat N times based on certain conditions like certain values on the same field or different fields. PAN 210 suggest using keywords “repeat” and “cond” together to represent such fields.

There are cases like a field repeats until the end of the message. In this case, the length field may not be present in the message, but it would be based on the number of bytes received on the message. PAN 210 provides a keyword “msglen” to represent these types of fields.

The drawing FIG. 10 A shows a simple PDU definition. The drawing FIG. 10 B shows the PAN representation for the PDU shown in drawing FIG. 10 A.

PAN 210 provides facilities to provide the values for fields. The values to be encoded for fields can be provided in PAN specifications. The expected values for validation also can be provided in PAN specifications. The values for validation can be direct simple values or it can be list of values to check or it can be range or it might be needed to check against run time variables or expressions. Multiple instances of same type of PDUS can be specified.

The values can be specified as numbers or strings based on the type of the fields. PAN 210 supports using run time variables in representing values. PAN 210 also supports using expressions to represent values.

The drawing FIG. 10 C shows the PAN specification with values for the PDU shown in drawing FIG. 10 A.

PANC 220 is a compiler tool. It analyzes the PAN specifications and generates the following outputs.

PDU structures 230

Coding rules 231

PDU data 232

PDU structures 230 contain the data structures to hold the PDU fields. These data structures are constructed using high level programming language data types. The drawing FIG. 10 D shows the PDU structures 230 for the PAN specifications shown in drawing FIG. 10 B.

Coding rules 231 contain the structural information about the PDU fields and the PDU structures. Coding rules 231 has all the information about the PDU fields including the field name, type and length. Coding rules do not contain any programming functions or procedures to encode or decode. Coding rules contains data about the PDU fields.

GCODEC 240 uses this information to understand the PDU fields to encode, decode and process. The drawings FIG. 10 E, and FIG. 10 F show the coding rules for the PAN specifications shown in drawing FIG. 10 B.

PDU data 232 contains the values for the PDU fields provided in PAN specifications. PDU data represents these values as instances of PDU structures 230. In case of multiple values specified for any fields, PDU data uses additional arrays of structures to store the specified values. The drawings FIG. 10 G shows the PDU data for the PAN specifications shows in drawing FIG. 10 C.

GCODEC 240 is a library of generic procedures to encode, decode and process the PDUS. GCODEC 240 generic procedures use coding rules 231 to understand the PDU specific information. GCODEC 240 library consists of four components encode 310, decode 320, process 330 and display 340 as shown in drawing FIG. 3.

Encode 310 reads the values from PDU data 232 and pack them as PDU buffer 280. Encode process is shown in drawing FIG. 4. Encode 310 has generic procedures to encode different types of PDU fields. Encode 310 supports encoding variable length fields and optional fields. Encode 310 contains the following key procedures.

Encode_pdu—This is the main encode procedure. This is used by applications and send_pdu procedure of PCO 250. This encode_pdu procedure uses encode_record procedure to encode the given PDU.

Encode_record—This procedure is used to encode group fields record and set. It uses encode_bits to encode the member fields of the given group field. It invokes by itself recursively to encode the nested group fields.

Encode_bits—This procedure is used to encode simple fields of type byte1, byte2, byte4, bits, hex, char IPAddr, IPMask and MACAddr. If values are specified using run time variables or expressions, this procedure evaluates them to get the value to be encoded.

Decode 320 decodes the values from PDU buffer 280 and populates PDU structures 231 with decoded values to form PDU data 232. Decode process is shown in drawing FIG. 5. Decode 320 has generic procedures to decode different types of PDU fields. Decode 320 supports decoding variable length fields and optional fields. Decode 320 contains the following key procedures.

decode_pdu—This is the main decode procedure. This is used by applications and receive_data procedure of PCO 250. This decode_pdu procedure uses decode_record procedure to decode the given PDU buffer.

decode_record—This procedure is used to decode record group field. It uses decode_bits, decode_set to decode the member fields of the given record. It invokes by itself recursively to decode the nested records.

decode_set—This procedure is used to decode set group field. It uses decode_record to decode the member fields of the given set.

decode_bits—This procedure is used to decode simple fields of type byte1, byte2, byte4, bits, hex, char IPAddr, IPMask and MACAddr.

Process 330 provides validation support. It decodes the PDU buffer 280 and validate against the given PDU data 232. Process 330 provides the validated result as pass or fail. Process 330 is shown in the drawing 6.

Process 330 decodes all the fields in the PDU buffer. It compares the decoded values against the values specified in given PDU data. The values specified in PDU data could be direct simples values or list of values or range of values. Process 330 can evaluate the run time expressions also to validate any fields. It can validate optional fields as well as variable length fields. It can validate all the fields or only a few fields as specified in PDU data. Process 330 has generic procedures to decode and validate different types of PDU fields. Process 330 contains the following key procedures.

process_pdu—This is the main process procedure. This is used by applications and receive_pdu procedure of PCO 250. This process_pdu procedure uses process_record procedure to decode and validate the given PDU buffer.

process_record—This procedure is used to decode and validate record group field. It uses process bits, process_set to decode and validate the member fields of the given record. It invokes by itself recursively to decode and validate the nested records.

process_set—This procedure is used to decode and validate set group field. It uses process_record to decode and validate the member fields of the given set.

process_bits—This procedure is used to decode and validate simple fields of type byte1, byte2, byte4, bits, hex, char IPAddr, IPMask and MACAddr.

Display 340 decodes the values from PDU buffer 280 and prints them as tree structured ascii text. This text output is useful to display the PDUS in graphical user interfaces for protocol testing applications. Display process is shown in drawing FIG. 7. Display 340 has generic procedures to decode and display different types of PDU fields. Display 340 supports decoding and displaying variable length fields and optional fields. Display 340 contains the following key procedures.

display_pdu—This is the main display procedure. This is used by applications and PCO 250 for logging the PDUS sent or received. This display_pdu procedure uses display_record procedure to decode and display the given PDU buffer.

display_record—This procedure is used to decode and display record group field. It uses display bits, display_set to decode and display the member fields of the given record. It invokes by itself recursively to decode and display the nested records.

display_set—This procedure is used to decode and display set group field. It uses display_record to decode and display the member fields of the given set.

display_bits—This procedure is used to decode and display simple fields of type byte1, byte2, byte4, bits, hex, char IPAddr, IPMask and MACAddr.

The drawing FIG. 10 H shows the display text of the PDU shown in drawing FIG. 10 A.

PCO 250 provides the enhanced send and receive functionality to send or receive PDU buffers. PCO 250 uses under lying basic send and receive procedure of the interfaces involved. PCO 250 can be developed on top of any communication interfaces like sockets, drivers or physical interfaces. PCO 250 uses GCODEC 240 to provide the enhanced send and receive features. PCO 250 contains three components send 810, receive 820 and utility 830 as shown in drawing FIG. 8.

The send 810 component provides the transfer functionality to send the PDU buffer on given interface. It provides two send procedures as send_buf and send_pdu. The send_buf function takes a PDU buffer and directly sends it over the interface. The send_pdu function takes PDU data as input and uses encode function to encode the given PDU data in PDU buffer. The encoded PDU buffer is sent over the given interface.

The receive 820 component provides the receive functionality on given interface. It provides three receive procedures as receive_buf, receive_data and receive_pdu. The receive_buf receives the raw PDU buffer from the given interface. The receive_data procedure receives the PDU buffer and decodes the received buffer as PDU data. The receive_data returns the decoded PDU data. It used decode function of GCODEC 240 to decode the received PDU. The receive_pdu procedure receives the PDU buffer and validate the received PDU against given PDU data. The receive_pdu returns result as received or not received. It uses process procedure of GCODEC 240 to validate the received PDU.

The above three receive procedures supports timeout feature. If any PDU or expected PDU is not received within given time, it returns errors. This timeout feature relieves applications from error prone timer processing and waiting loops.

The utility 830 provides the facilities for the following functionalities.

PCO management—PCO management provides procedures to create, delete, stop and run the PCO.

PDU logging—This provides procedure to log the raw PDU buffer and display text of sent or received PDU buffer. This uses generic display procedure 340 of GCODEC 240.

Timers—This provides the required timer operations.

As shown in drawing FIG. 9, the components disclosed in this invention relieve application software from PDU specific operations. This helps application developers to focus on core applications for faster product development. It also opens up the ways to automate the applications since it has become simple now.

While this invention has been described with specific details and the drawings with simple PDUS, it is to be understood that the invention is not limited to these specific types of PDUS. To the contrary, it is intended to cover various modifications as would be apparent to those skilled in the art. Therefore, the scope of appended claims should be accorded the broadest interpretation so as to encompass all such modifications.

I claim:

1. A method for generically encode and decode PDUS comprising the steps of
(a) PDUS are represented in a formal notation, PAN
(b) a compiler tool, PANC, compiles the PAN specification of PDUS and generate the required information for encoding and decoding the PDUS
(c) generic encode procedures encode the PDUS to PDU buffer
(d) generic decode procedures decode the PDUS to PDU structure formats from given PDU buffer
(e) generic display procedure decode and display the PDUS in tree structure ascii text format

2. The method of claim 1 where in compiling the PAN specification of PDUS using compiler PANC involves the following details.
(a) PANC parses the PAN specifications and generate PDU structures and coding rules
(b) the generated PDU structures are the programming language data representation of PDU fields. These structures are used to store the contents of PDU fields in memory
(c) the coding rules contains the information about PDU fields. This information is used by encode, decode, display procedures to understand PDU specific formats. This information includes names of the PDU fields, type of the PDU fields, and size of the PDU fields.

3. The method of claim 1 where in generically encoding the PDUS involves the following details.
(a) a single generic encode procedure is used to encode all the PDUS specifiable in PAN representation.
(b) this generic encode procedure uses the coding rules generated PANC compiler to understand the PDU formats
(c) this generic encode procedure encodes the mandatory fields, optional fields, and variable length fields of PDUS

4. The method of claim 1 where in generically decoding the PDUS involves the following details.
(a) a single generic decode procedure is used to decode all the PDUS specifiable in PAN representation.
(b) this generic decode procedure uses the coding rules generated PANC compiler to understand the PDU formats
(c) this generic decode procedure decodes the mandatory fields, optional fields, and variable length fields of PDUS

5. The method of claim 1 where in generically displaying the PDUS involves the following details.
(a) a single generic display procedure is used to decode and display all the PDUS specifiable in PAN representation.
(b) this generic display procedure uses the coding rules generated PANC compiler to understand the PDU formats
(c) this generic display procedure decodes and displays the mandatory fields, optional fields, and variable length fields of PDUS

6. A method for generically encode and validate PDUS using predefined values comprising the steps of
(a) values for PDUS are specified in formal notation PAN
(b) a compiler tool, PANC, compiles the PAN specification of PDU values and generate the PDU data
(c) generic encode procedures encode the PDU data to PDU buffer
(d) generic process procedures decode and validate the PDU buffers using the given PDU data

7. The method of claim 6 where in specifying PDU values in PAN notation involves the following details.
(a) values for PDU fields are specified in PAN specifications
(b) values for encoding PDUS are specifiable using numbers and alphanumeric strings according to the types of the fields.
(c) values for validating PDUS are specifiable either us direct values of numbers and alphanumeric strings or using the expressions. The expression can provides list of values to validate or range of values to validate. The expression can also use run time variables to validate against variable values. The expressions can be the combination of multiple expressions using logical or relation operators.
(d) multiple instances of PDUS can be specified for PDUS with different values

8. The method of claim 6 where in compiling the PAN specification of PDUS values using compiler PANC involves the following details.
(a) PANC parses the PAN specifications of PDU values and generate PDU data
(b) the generated PDU data are the data instances of PDU structures holding the data provided in PAN specifications

9. The method of claim 6 where in generically processing the PDUS involves the following details.
(a) a single generic process procedure is used to decode and validate all the PDUS specifiable in PAN representation.
(b) this generic process procedure uses the values from PDU data to validate the given PDU.
(c) this generic process procedure uses the coding rules generated by PANC compiler to understand the PDU formats
(d) this generic process procedure decodes and validates the mandatory fields, optional fields, and variable length fields of PDUS

10. A method for providing enhanced send and receive functionalities by combing generic codec and transport procedures comprising the steps of
(a) a single generic send procedure encodes the given PDU and transfers over the interface
(b) a single generic receive procedure receives the PDUS and validates against the given expected values

11. The method of claim 10 where in generic send method involves the following steps.
(a) the given PDU data is encoded as PDU buffer using generic encode procedure provided by codec
(b) the encoded PDU buffer is transferred over the underlying interface using interface specific send procedures

12. The method of claim 10 where in generic receive method involves the following steps.
(a) the PDUS are received from the underlying interface using interface specific receive procedures
(b) if the PDUS are received within expected time, the received PDUS are validated using generic process procedure provide by codec.
